(19) United States
(12) Patent Application Publication
(10) Pub. No.: US 2005/0172993 A1
(43) Pub. Date: Aug. 11, 2005

(54) Thermoelectric generator for internal combustion engine

(76) Inventors: Kouji Shimoji, Okazaki-shi (JP); Kouichi Suzuki, Toyoake-shi (JP); Shinya Matsubara, Kariya-shi (JP)

Correspondence Address: KENYON & KENYON, 1 BROADWAY, NEW YORK, NY, 10004, US

(21) Appl. No.: 11/049,646

(22) Filed: Feb. 4, 2005

(30) Foreign Application Priority Data
Feb. 5, 2004 (JP) 2004-029334

(51) Int. Cl. H01L 35/28; H01L 35/30

(52) U.S. Cl. 136/208; 136/205

(57) ABSTRACT

A thermoelectric generator for an internal combustion engine that prevents a thermoelectric generation element from being damaged. The thermoelectric generator includes a casing, which is arranged in an exhaust passage, and a sleeve. A cooling mechanism is arranged outside the sleeve. Thermoelectric generation elements are arranged between the sleeve and the cooling mechanism in a manner movable relative to both the sleeve and the,cooling mechanism. The thermoelectric generation elements convert heat energy from exhaust in the exhaust passage to electric energy.

### BACKGROUND OF THE INVENTION

The present invention relates to a thermoelectric generator, and more particularly, to a thermoelectric generator for converting thermal energy of exhaust from an internal combustion engine to electric energy.

The generation of electric power using a thermoelectric generation element, which converts thermal energy to electric energy, is known in the prior art. The thermoelectric generation element makes use of the Seeback effect in which the temperature difference between two ends (high temperature portion and low temperature portion) of a metal or semiconductor piece generates a potential difference between the high temperature and low temperature portions of the metal or semiconductor piece. A larger temperature difference increases the electric power generated by the thermoelectric generation element.

FIG. 1 shows an example of the structure of a thermoelectric generation element. As shown in FIG. 1, the thermoelectric generation element includes n-type and p-type semiconductors. Each n-type semiconductor has a high temperature portion, which functions as a positive pole, and a low temperature portion, which functions as a negative pole. To generate a large amount of electric power, the n-type and p-type semiconductors are alternately connected in series to form an electrode module.

Japanese Laid-Open Patent Publication No. 2002-325470 describes an example of an application for such a thermoelectric generation element. Specifically, a frame is arranged in an exhaust passage of an internal combustion engine. One side of a thermoelectric generation element contacts the peripheral surface of the frame. The opposite side of the thermoelectric generation element contacts a cooling mechanism. By arranging the thermoelectric generation element in this manner, thermal energy from exhaust is converted to electric energy.

An adhesive fixes at least either the frame to the thermoelectric generation element or the thermoelectric generation element to the cooling mechanism.

A fixed member (frame or the cooling mechanism), to which the thermoelectric generation element is fixed, may have a thermal expansion coefficient differing from that of the thermoelectric generation element. In this case, when the temperature of the fixed member and thermoelectric generation element changes, the deformation amount of the fixed member differs from that of the thermoelectric generation element. Thus, thermal stress acts on the thermoelectric generation element. This may inflict damage on the thermoelectric generation element.

### SUMMARY OF THE INVENTION

It is an object of the present invention to provide a thermoelectric generator for an internal combustion chamber that reduces the possibility of a thermoelectric generation element being damaged.

One aspect of the present invention is a thermoelectric generator for an internal combustion engine connected to an exhaust passage. The generator includes a hot member arranged in the exhaust passage. A cold member is arranged outside the hot member. A thermoelectric generation element, arranged between the hot and cold members in a manner movable relative to both the hot and cold members, converts heat energy from exhaust in the exhaust passage to electric energy.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic diagram showing the structure of a thermoelectric generation element;

FIG. 2 is a schematic diagram showing an exhaust system of a vehicle incorporating a thermoelectric generator according to a preferred embodiment of the present invention;

FIG. 3 is a perspective view showing the thermoelectric generator;

FIG. 4 is a partial cross-sectional view showing the thermoelectric generator of FIG. 2;

FIG. 5 is a cross-sectional view taken along line 5-5 in FIG. 4;

FIG. 6 is a schematic cross-sectional view showing a thermoelectric generator according to another embodiment of the present invention in a direction perpendicular to the flow direction of exhaust;

FIG. 7 is a schematic cross-sectional view showing a thermoelectric generator according to a further embodiment of the present invention in a direction perpendicular to the flow direction of exhaust;

FIG. 8 is a schematic cross-sectional view showing a thermoelectric generator according to still another embodiment of the present invention in a direction perpendicular to the flow direction of exhaust; and

FIG. 9 is a schematic diagram showing the location of a thermoelectric generator according to a further embodiment of the present invention.

### DETAILED DESCRIPTION OF THE PREFERRED EMBODIMENTS

In the drawings, like numerals are used for like elements throughout.

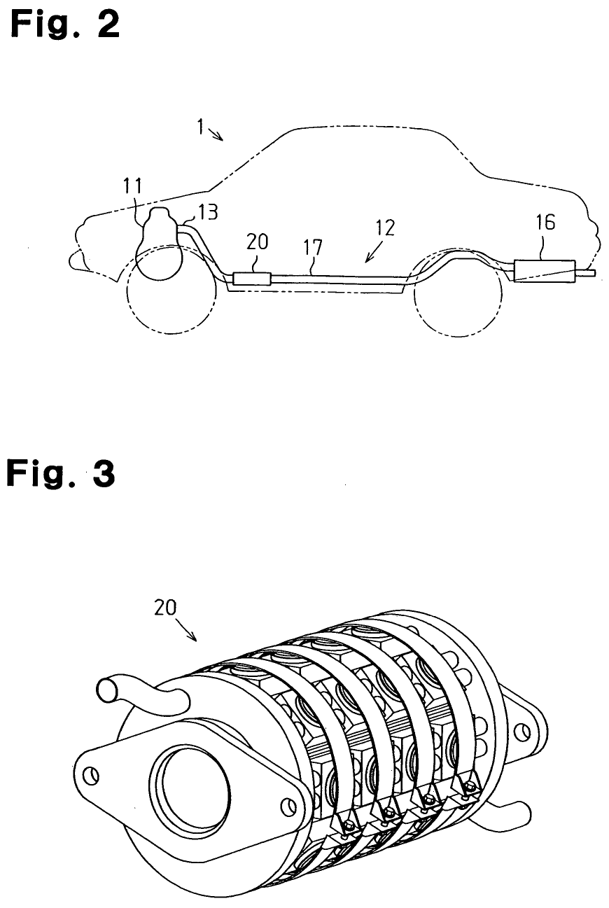

A thermoelectric generator 20 according to a preferred embodiment of the present invention will now be discussed with reference to FIGS. 2 to 5.

FIG. 2 schematically shows an exhaust system 12 of a vehicle 1 incorporating the thermoelectric generator 20.

As shown in FIG. 2, the exhaust system 12 includes an exhaust passage 17. From the upstream side with respect to the flow of exhaust, the exhaust passage 17 includes an exhaust manifold 13, the thermoelectric generator 20, and a muffler 16. In the exhaust system 12, exhaust emitted from an internal combustion engine 11 passes through the exhaust manifold 13, the thermoelectric generator 20, and the muffler 16 to be discharged into the atmosphere.

The thermoelectric generator 20 will now be discussed with reference to FIGS. 3 to 5.

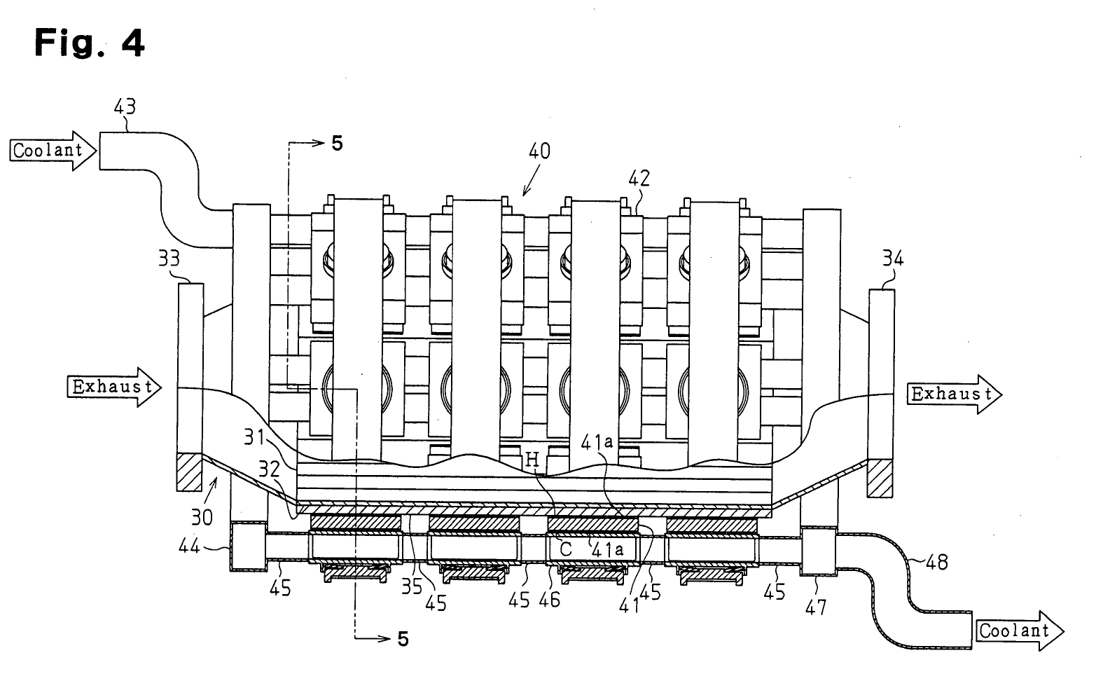

FIG. 3 is a perspective view showing the thermoelectric generator 20. FIG. 4 is a partial cross-sectional view showing the thermoelectric generator 20. As shown in FIG. 4, the thermoelectric generator 20 includes an exhaust catalyst 30 and a thermoelectric generator stack 40.

The exhaust catalyst 30 includes a cylindrical catalyst carrier 31 and a casing 32 accommodating the catalyst carrier 31. The catalyst carrier 31 carries a catalyst. When the catalyst reaches a predetermined activation temperature, the catalyst purges exhaust components, such as, hydrocarbon (HC), carbon monoxide (CO), and nitrogen oxides (NOx).

The casing 32 is made of stainless steel, which is a material having a relatively high thermal conductivity and a relatively superior anti-corrosion property. In this embodiment, austenite stainless steel (e.g., SUS 303 or SUS 304) having a thermal expansion coefficient that is relatively higher than other stainless steels is used to form the casing 32. The casing 32 has open ends. An upstream flange 33 connected to the exhaust manifold 13 is arranged on one end of the casing 32. A downstream flange 34 connected to the exhaust passage 17 is arranged on the other end of the casing 32. In this manner, the exhaust passage 17 forms part of the casing 32 and at least part of a hot member. The casing 32 is press-fitted in a sleeve 35. The sleeve 35 is made of a material having a relatively high thermal conductivity and a relatively superior anti-corrosion property (e.g., stainless steel, aluminum alloy, or copper). Thus, the sleeve 35 easily transmits heat to the casing 32. The sleeve 35 forms part of the hot member.

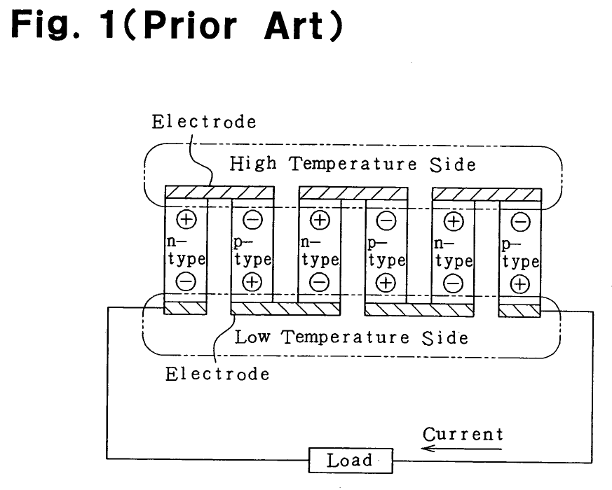

The thermoelectric generator stack 40 includes a plurality of thermoelectric generation elements 41 and a cooling mechanism 42. Each thermoelectric generation element 41 has the same structure as that shown in FIG. 1. In this embodiment, each thermoelectric generation element 41 has two sides on which electrodes are arranged. The electrodes are coated by an amorphous carbon film 41a (DLC film). The friction coefficient of the amorphous carbon film 41a is relatively small. Further, the amorphous carbon film 41a has superior electric insulation, thermal conductivity, heat resistant, and abrasion resistant properties.

The thermoelectric generation elements 41 are arranged on the peripheral surface of the sleeve 35 in the axial direction of the exhaust catalyst 30, that is, in the flow direction of exhaust. The surface contacting the peripheral surface of the sleeve 35 in each thermoelectric generation element 41 (hereinafter referred to as surface H) functions as a high temperature surface.

The cooling mechanism 42 is arranged on the surface of each thermoelectric generation element 41 that is opposite the surface H. Coolant, which functions as a cooling medium, flows through the cooling mechanism 42. From the upstream side with respect to the flow direction of the coolant, the cooling mechanism 42 includes an intake pipe 43, a first collection portion 44, distribution pipes 45, cooling portions 46, a second collection portion 47, and a discharge pipe 48. The cooling mechanism 42 functions as a cold member.

The first collection portion 44 and the second collection portion 47 are annular pipes that are arranged outside the peripheral surface of the casing 32. The first collection portion 44 is arranged upstream from the second collection portion 47 with respect to the exhaust flow direction. The distribution pipes 45, which extend in the axial direction of the exhaust catalyst 30, connect the first collection portion 44 and the second collection portion 47.

Each distribution pipe 45 includes the cooling portions 46, which cool the associated thermoelectric generation elements 41. The surface of each thermoelectric generation element 41 contacting the associated cooling portion 46 (hereafter referred to as surface C) functions as a low temperature surface. Coolant is drawn into each cooling portion 46 through the associated distribution pipe 45.

The intake pipe 43 is connected to an upper part of the first collection portion 44. Coolant is drawn into the first collection portion 44 through the intake pipe 43. The discharge pipe 48 is connected to a lower part of the second collection portion 47 at the downstream side with respect to the flow of exhaust. Coolant is discharged into a cooling system from the second collection portion 47 through the discharge pipe 48. In this arrangement, coolant flows downward in the cooling mechanism 42 and in the direction of the exhaust flow.

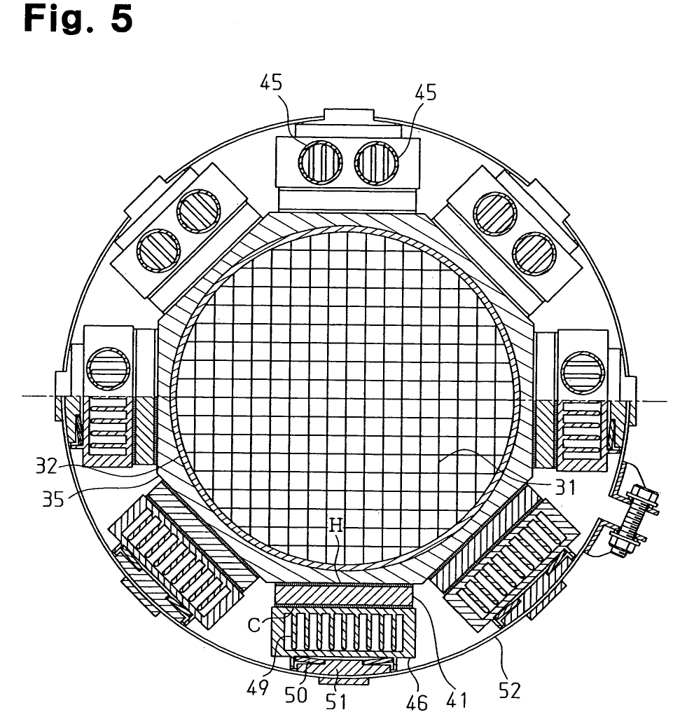

FIG. 5 is a cross-sectional view taken along line 5-5 in FIG. 4. As shown in FIG. 5, the catalyst carrier 31 is inserted in the casing 32. The casing 32 is inserted in the sleeve 35, which is octagonal. The carrier 31 is extrusion molded and made of metal. More specifically, the carrier 31 has a honeycomb structure. Pores extend through the carrier 31 in the axial direction. The wall surfaces defining the pores are formed from sintered metal. In the preferred embodiment, an alloy produced by adding chromium or aluminum to steel is used as the sintered metal. However, any metal may be used as long as it has a superior heat resistant property.

The sleeve 35 has a peripheral surface including eight flat planes extending in the axial direction of the casing 32.

The thermoelectric generation elements 41 are arranged in contact with the peripheral surface of the sleeve 35. In this embodiment, four thermoelectric generation elements 41 are arranged on each of the eight flat planes of the sleeve 35 in the axial direction of the sleeve 35. Thus, a total of thirty two (8×4) thermoelectric generation elements 41 are arranged on the peripheral surface of the sleeve 35. Further, the thermoelectric generation elements 41 are arranged at equal angular intervals (45°).

In each thermoelectric generation element 41, the surface C is in contact with the associated cooling portion 46. Further, as shown in FIG. 5, a plurality of heat radiating fins 49 are formed in each cooling portion 46.

A Belleville spring 50 and a washer 51 are arranged on the surface of each cooling portion 46 opposite the surface contacting the associated thermoelectric generation element 41. A band 52 fixes each cooling portion 46 to the associated thermoelectric generation element 41 by means of the corresponding Belleville spring 50 and washer 51. Accordingly, the band 52, which functions as a fastening member, integrally fastens the cooling portion 46, the associated thermoelectric generation elements 41, the sleeve 35, and the casing 32. Each thermoelectric generation element 41 is held in a state pressed between the cooling portion 46 and the sleeve 35. In this manner, each thermoelectric generation element 41 is held in a movable manner between the associated cooling portion 46 of the cooling mechanism 42 and the sleeve 35, which forms part of the hot member. In this embodiment, the band 52 is made of metal. However, the band 52 may be made of other materials. Further, an elastic member such as a rubber member may be used in lieu of the Belleville spring 50.

In the thermoelectric generator 20, each thermoelectric generation element 41 is held in a state pressed between the sleeve 35 and the cooling portion 46. In other words, the thermoelectric generation element 41 is held in a state in which it is not completely fixed to the sleeve 35 or the cooling portion 46. Accordingly, the thermoelectric generation element 41 is movable relative to both the sleeve 35 and the cooling portion 46. When the deformation amount of the thermoelectric generation elements 41 differs from that of the sleeve 35 due to different thermal expansion coefficients, the thermoelectric generation elements 41 and the sleeve 35 move relative to each other. This reduces the stress acting on the thermoelectric generation elements 41. As a result, the thermal stress, produced by the difference in the thermal expansion coefficients between the thermoelectric generation elements 41 and the sleeve 35, acting on the cooling portions 46 is reduced. In the same manner, since the thermoelectric generation elements 41 are movable relative to the cooling portions 46, the application of thermal stress, which is produced by the difference in the thermal expansion coefficients between the thermoelectric generation elements 41 and the cooling portion 46, to the thermoelectric generation elements 41 is suppressed. This decreases the possibility of damages being inflicted on the thermoelectric generation elements 41.

The thermoelectric generation elements 41 are movable relative to both the sleeve 35 and the cooling portions 46. Further, the thermoelectric generation elements 41 directly contact the sleeve 35 and the cooling portions 46. This ensures the generation of electric power through the temperature difference between the sleeve 35 and the cooling portions 46.

The band 52 integrally fastens the thermoelectric generation elements 41, the sleeve 35, and the cooling portions 46. In this manner, the thermoelectric generation elements 41 are held in a state pressed by a simple structure.

The thermoelectric generation elements 41 are not completely fixed. This facilitates the replacement of the thermoelectric generation elements 41.

By increasing the adhesion between the thermoelectric generation elements and the hot member or the adhesion between the thermoelectric generation elements and the cold member, the heat transmitted from the hot member to the thermoelectric generation elements or from the thermoelectric generation elements to the cold member may be increased to increase the electric power generated by the thermoelectric generation elements. However, if the pressure applied between the thermoelectric generation elements 41 and the hot member is increased to increase adhesion, the hot member may be deformed. To suppress such deformation of the hot member, in this embodiment, the sleeve 35, which functions as the hot member, is arranged on the peripheral surface of the casing 32, and the surface H of each thermoelectric generation element 41 is in contact with the sleeve 35. The sleeve 35 increases the rigidity of the hot member, which includes the sleeve 35. Accordingly, the deformation of the hot member (casing 32) is suppressed even when the pressure is increased as described above.

Each thermoelectric generation element 41 is generally flat, and the sleeve 35 is polygonal. In other words, the surfaces of the sleeve 35 and the surfaces H of the thermoelectric generation elements 41 are shaped in correspondence with one another. This ensures the adhesion between the surfaces H of the thermoelectric generation elements 41 and the sleeve 35.

The casing 32 is made of austenite stainless steel. Thus, in comparison with when using other stainless steels, the thermal expansion of the casing 32 is large. The radial expansion of the casing 32 urges the sleeve 35 toward the thermoelectric generation elements 41. This enhances the adhesion between the sleeve 35 and the thermoelectric generation elements 41 and increases the heat transmitted from the sleeve 35 to the thermoelectric generation elements 41. As a result, the electric power generated by the thermoelectric generation elements 41 is further increased.

The exhaust catalyst 30 is arranged in the casing 32. When purging exhaust, chemical reaction heat raises the temperature of the exhaust catalyst 30. Thus, the temperature of the exhaust catalyst 30 is higher than that of the exhaust manifold 13 and the exhaust passage 17. This further increases the temperature of the casing 32 in comparison to when the exhaust catalyst 30 is not used. Accordingly, the temperature of the sleeve 35, which is in contact with the peripheral surface of the casing 32, becomes further higher. This further increases the amount of electric power generated by the thermoelectric generation elements 41. A further increase in the temperature of the sleeve 35 increases deformation caused by thermal expansion. However, even when thermal expansion deforms the hot member, the thermoelectric generator 20 prevents damages from being inflicted on the thermoelectric generation elements 41. Further, the exhaust catalyst 30 and the thermoelectric generator 20 are formed integrally. In this structure, the entire exhaust apparatus for the internal combustion engine is compact in comparison to when the exhaust catalyst 30 and the thermoelectric generator 20-are arranged separately in the exhaust passage 17.

The exhaust temperature rises when the internal combustion engine is operated in a state in which the engine speed and load are high. Thus, there is a tendency of deterioration occurring in the exhaust catalyst 30 due to the high temperature. In this embodiment, however, the heat of the exhaust catalyst 30 is consumed by the thermoelectric generation elements 41. This suppresses high temperature deterioration of the exhaust catalyst 30.

The carrier 31 of the exhaust catalyst 30 is made of metal. A metal carrier easily transmits the chemical reaction heat, which it generates, and exhaust heat. Accordingly, the temperature rising speed of a metal carrier is higher than that of a ceramic carrier. Thus, the temperature of a metal carrier becomes higher than that of a ceramic carrier more quickly. Accordingly, in this embodiment, the temperature of the high temperature surface H in each thermoelectric generation element 41 is readily and further increased. This further increases the electric power generated by the thermoelectric generation elements 41. Such a metal carrier may be formed from a plurality of laminated thin metal plates or from a spiral thin metal plate. However, the rigidity of a carrier formed from such thin plates is low. Accordingly, thin metal plates are easily deformed by external pressure. Thus, pressure applied via the casing 32 may deform the thin metal plate and, in some cases, inflict damage on the carrier. To avoid such a problem, the metal carrier 31 of this embodiment is extrusion molded. Further, a plurality of walls are formed integrally in the carrier 31. Thus, in comparison to a carrier formed from thin metal plates, the carrier 31 has high rigidity. Thus, the deformation amount resulting from external force is less. Accordingly, deformation of the carrier 31 is depressed even when the pressure applied to the carrier 31 is increased to increase the amount of generated electric power.

The cooling mechanism 42, through which coolant flows, is arranged on the low temperature surfaces C of the thermoelectric generation elements 41 to sufficiently cool the low temperature surfaces C. Further, coolant flows downward in the cooling mechanism 42. This produces a level difference between the upstream part of the cooling mechanism 42, in which the coolant is drawn into, and the downstream part. Thus, the coolant efficiently flows through the cooling mechanism 42. Further, the coolant flows in the same direction as the exhaust. In other words, the coolant flows downstream with respect to the flow of exhaust. This sufficiently cools the entire cooling mechanism 42.

The high temperature surface H and the low temperature surface C of each thermoelectric generation element 41 is coated by the amorphous carbon film 41a. The amorphous carbon film 41a, or the diamond-like carbon (DLC) film, has a relatively small friction coefficient. Thus, the movement resistance between the thermoelectric generation elements 41 and the member contacting the thermoelectric generation elements 41 (the sleeve 35 and the cooling portions 46) is relatively small. Accordingly, the thermoelectric generation element 41 easily moves on the sleeve 35 and the cooling portions 46. This sufficiently reduces the possibility of damages being inflicted on the thermoelectric generation elements 41. The amorphous carbon film 41a has a relatively superior electric insulation property. This ensures insulation between the high temperature side electrodes of the thermoelectric generation elements 41 and between the low temperature side electrodes of the thermoelectric generation elements 41. The amorphous carbon film 41a has a relatively high thermal conductivity. This ensures the generation of electric power in correspondence with the temperature difference between the hot and cold members. Further, the amorphous carbon film 41a has relatively superior heat resistance and abrasion resistance properties. This ensures the generation of electric power over a long period.

The thermoelectric generator 20 of this embodiment has the advantages described below.

(1) The thermoelectric generation elements 41 are movable relative to both the hot member (sleeve 35) and the cold member (cooling portions 46). This reduces the possibility of the difference between thermal expansion coefficients of the hot and cold members and the thermoelectric generation elements 41 inflicting damage on the thermoelectric generation elements 41.

The thermoelectric generation elements 41 are movable relative to both the hot member and the cold member. Further, the thermoelectric generation elements 41 directly contact the hot and cold members. This ensures the generation of electric power in correspondence with the temperature difference between the hot and cold members in an optimal manner.

(2) Each thermoelectric generation element 41 is held in a state pressed by the hot and cold members. Accordingly, the thermoelectric generation element 41 is not completely fixed to the hot and cold members. Thus, the thermoelectric generation element 41 is movable relative to the hot and cold members.

(3) The thermoelectric generation elements 41 are not completely fixed. This facilitates the replacement of the thermoelectric generation elements 41.

(4) The bands 52 integrally fasten the thermoelectric generation elements 41, the hot member, and the cold member. Thus, the thermoelectric generation elements 41 are held in a pressed state by a simple structure.

(5) The sleeve 35, which forms part of the hot member, is arranged on the peripheral surface of the casing 32, which forms part of the exhaust passage. This increase the electric power generated by the thermoelectric generation elements 41 and suppresses deformation of the casing 32.

(6) The surfaces of the sleeve 35, contacting the surfaces H of the thermoelectric generation elements 41, are shaped in correspondence with the surfaces H. More specifically, the sleeve 35 is polygonal and has a plurality of flat surfaces. This ensures the adhesion between the surfaces H of the thermoelectric generation elements 41 and the sleeve 35, which forms part of the hot member.

(7) The casing 32 is formed from austenite stainless steel. This further improves the adhesion between the sleeve 35 and the thermoelectric generation elements 41 and further increases the electric power generated by the thermoelectric generation elements 41.

(8) The exhaust catalyst 30 is arranged in the casing 32. This further raises the temperature of the sleeve 35 and increases the electric power generated by the thermoelectric generation elements 41. Further, in this embodiment, even if thermal expansion deforms the hot member, which includes the sleeve 35, the possibilities of damage being inflicted on the thermoelectric generation elements 41 is reduced. Accordingly, even if a structure for raising the temperature of the sleeve 35 is employed, the possibility of damage being inflicted on the thermoelectric generation elements 41 is reduced.

(9) The exhaust catalyst 30 and the thermoelectric generator 20 are assembled integrally with each other. Thus, the entire exhaust apparatus for the internal combustion engine is compact.

(10) The exhaust temperature rises when the internal combustion engine is operated in a high speed and high load state. In such a state, deterioration caused by high temperature tends to occur in the exhaust catalyst 30. In this embodiment, such high temperature deterioration of the exhaust catalyst 30 is suppressed in an optimal manner.

(11) The carrier 31 of the exhaust catalyst 30 is an extrusion molded metal carrier. This readily and further increases the temperature of the high temperature surface H in each thermoelectric generation element 41. Accordingly, the electric power generated by the thermoelectric generation element 41 is further increased.

Deformation of the carrier 31 is suppressed in an optimal manner since the carrier 31 is an extrusion molded metal carrier even if the pressure applied to each thermoelectric generation element 41 is increased.

(12) Coolant flows downward in the cooling mechanism 42. Thus, coolant flows efficiently through the cooling mechanism 42, and the low temperature surface C of each thermoelectric generation element 41 is cooled in an optimal manner.

Further, coolant flows in the same direction as exhaust. Accordingly, the entire cooling mechanism 42 is cooled in an optimal manner.

(13) The two sides of each thermoelectric generation element 41 are coated by the amorphous carbon films 41a. Thus, the movement resistance between the thermoelectric generation elements 41 and the member contacting the thermoelectric generation elements 41 (the sleeve 35 and the cooling portions 46) is small. This sufficiently reduces the possibility of damage being inflicted on the thermoelectric generation elements 41. Further, insulation between the high temperature side electrodes of the thermoelectric generation elements 41 and between the low temperature side electrodes of the thermoelectric generation elements 41 is ensured. Additionally, the generation of electric power corresponding to the temperature difference between the hot and cold members is ensured. Accordingly, the generation of electric power over a long period is ensured.

It should be apparent to those skilled in the art that the present invention may be embodied in many other specific forms without departing from the spirit or scope of the invention. Particularly, it should be understood that the present invention may be embodied in the following forms.

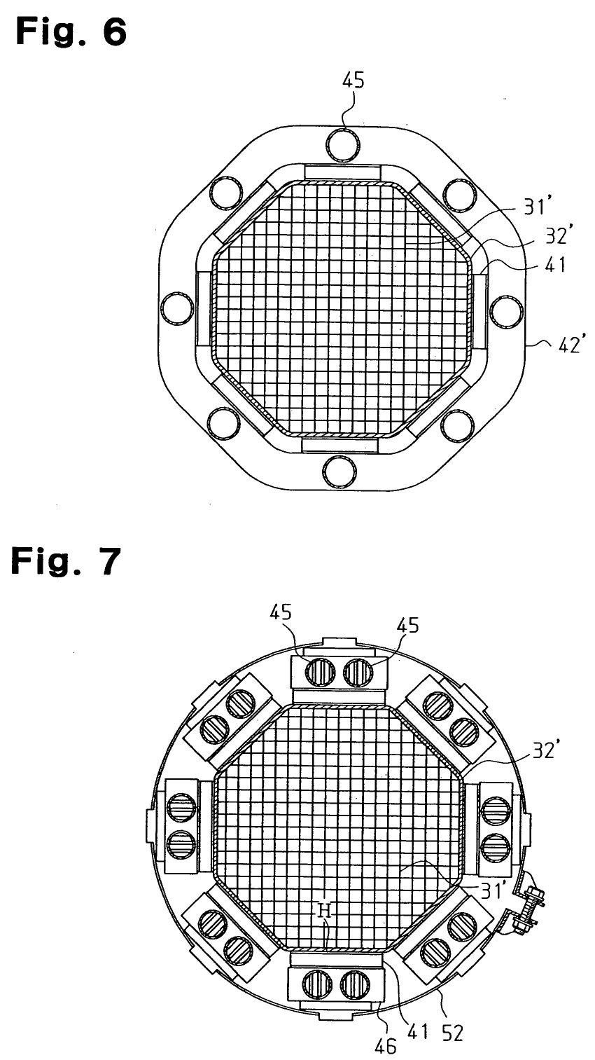

In the preferred embodiment, the bands 52 integrally fasten the cooling portions 46, the thermoelectric generation elements 41, and the sleeve 35. Instead, the thermoelectric generation elements 41 may be held in a pressed state as shown in FIG. 6.

More specifically, a generally polygonal carrier 31′ is inserted in a polygonal casing 32′. A cooling mechanism 42′ has a plurality of cooling portions 46 formed in an integral manner and extending in the circumferential direction of the casing 32′ arranged in the exhaust flow direction. The thermoelectric generation elements 41 are loosely fastened to the inner surface of the cooling mechanism 42′. Further, the thermoelectric generation elements 41 and the cooling mechanism 42′ are press fitted to the peripheral surface of the casing 32′. In this manner, by loosely fastening the thermoelectric generation elements 41 to the cold member and press fitting the cold member and the thermoelectric generation elements to the peripheral surface of the hot member, the thermoelectric generation elements 41 are press fitted between the hot member and the cold member. In this structure, the bands 52 may be eliminated. Accordingly, with a simple structure, the thermoelectric generation elements 41 are held in a state pressed toward the hot and cold members.

The hot member and the thermoelectric generation elements 41 may be loosely fastened, and the hot member and the thermoelectric generation elements 41 may be press fitted to the inner surface of the cold member. Alternatively, the thermoelectric generation elements may be press fitted between the hot member and the cold member.

Referring to FIG. 7, the sleeve 35 may be eliminated. In this case, the carrier 31′ and the casing 32′ of FIG. 6 are used so that the entire surface H of each thermoelectric generation element 41 directly contacts the peripheral surface of the casing 32′. Accordingly, heat is transmitted from the carrier 31′ to the thermoelectric generation elements 41 in an optimal manner.

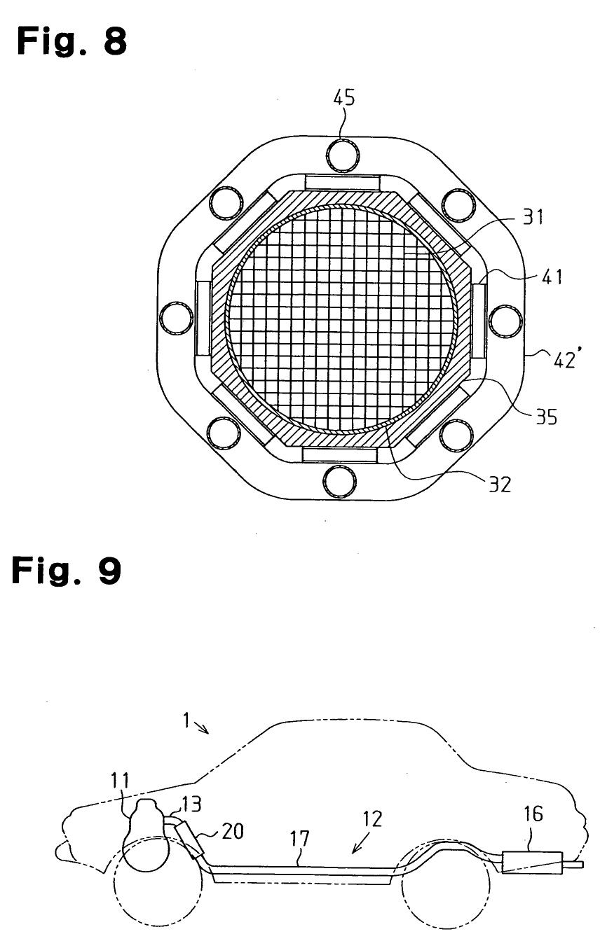

As described above, in FIG. 6, the sleeve 35 is eliminated, and the thermoelectric generation elements 41 are press fitted between the hot and cold members. Instead, referring to FIG. 8, the sleeve 35 may be used, and the thermoelectric generation elements 41 may be press fitted between the sleeve 35 and the cold member.

The sleeve 35 of the preferred embodiment may be formed from austenite stainless steel. This increases thermal expansion of the sleeve 35 and improves adhesion between the thermoelectric generation elements 41 and the sleeve 35. As a result, the heat transmitted from the sleeve 35 to the thermoelectric generation elements 41 increases. This further increases the electric power generated by the thermoelectric generation elements 41.

The sleeve 35 and the casing 32 may be formed integrally, and the exhaust catalyst may be inserted in the sleeve 35.

As described above, it is preferred that the carrier 31 be an extrusion molded metal carrier. However, the carrier 31 may be a ceramic carrier or a metal carrier formed from a thin metal plate.

In each embodiment of the present invention, any exhaust catalyst may be used as long as heat is generated when purging exhaust components.

The carrier in the casing 32 or the casing 32′, that is, the exhaust catalyst, may be eliminated. In other words, the present invention may be applied to a structure in which the thermoelectric generation elements 41 are arranged on the peripheral surface of an exhaust pipe forming the exhaust system.

In the preferred embodiment, the two sides of the thermoelectric generation elements 41 are coated by the amorphous carbon film 41a. Any film may be used for the coating as long as it has small friction coefficient, superior electric insulation, thermal transmission, heat resistant, and abrasion resistant properties. Further, one side of each thermoelectric generation element 41 (e.g., surface H) may be covered by the amorphous carbon film 41a, while the other side of each thermoelectric generation element 41 (e.g., surface C) is coated by a film differing from the amorphous carbon film 41a.

There may be any number of the thermoelectric generation elements 41.

In the preferred embodiment, coolant is used as the cooling medium of the cooling mechanism 42. However, any cooling medium may be used as long as the cooling mechanism 42 can be cooled.

The cooling mechanism 42 is a so-called water-cooled mechanism. Instead, an air-cooled mechanism including heat radiating fins may be used.

The Belleville springs 50 and the washers 51 may be eliminated, and the bands 52 may directly fasten the cooling portions 46.

As shown in FIG. 9, the thermoelectric generator 20 may be arranged directly below the exhaust manifold 13. This would contribute to flattening the underfloor of the vehicle 1 and increase the interior space of the vehicle 1.

The present examples and embodiments are to be considered as illustrative and not restrictive, and the invention is not to be limited to the details given herein, but may be modified within the scope and equivalence of the appended claims.

1. A thermoelectric generator for an internal combustion engine connected to an exhaust passage, the generator comprising:
a hot member arranged in the exhaust passage;
a cold member arranged outside the hot member; and
a thermoelectric generation element, arranged between the hot and cold members in a manner movable relative to both the hot and cold members, for converting heat energy from exhaust in the exhaust passage to electric energy.

2. The generator according to claim 1, further comprising:
a holding member for holding the thermoelectric generation element in a state pressed between the hot and cold members.

3. The generator according to claim 2, wherein the thermoelectric generation element is press fitted between the hot and cold members.

4. The generator according to claim 1, wherein the thermoelectric generation element includes a first surface contacting the hot member and a second surface contacting the cold member, and the hot member includes:t
a hot body; and
a sleeve arranged outside the hot body in contact with the first surface.

5. The generator according to claim 4, wherein the sleeve includes a surface shaped to closely contact the first surface.

6. The generator according to claim 5, wherein the sleeve is polygonal.

7. The generator according to claim 1, wherein the hot member is formed from austenite stainless steel.

8. The generator according to claim 1, wherein the hot member has an opening, the generator further comprising:
an exhaust catalyst accommodated in the opening of the hot member.

9. The generator according to claim 8, wherein the exhaust catalyst includes an extrusion molded metal carrier.

10. The generator according to claim 1, wherein the cold member includes a cooling mechanism through which a cooling medium flows.

11. The generator according to claim 10, wherein the cooling mechanism is configured so that the cooling medium flows downward and in the direction that exhaust flows.

12. The generator according to claim 1, wherein the thermoelectric generation element includes a first surface contacting the hot member and a second surface contacting the cold member, the generator further comprising:
an amorphous carbon film coating at least one of the first and second surfaces.

13. The generator according to claim 1, further comprising:
a band for integrally holding the thermoelectric generation element, the hot member, and the cold member.

14. The generator according to claim 13, further comprising:
an elastic member arranged between the cold member and the band.
